(19) United States
(12) Patent Application Publication
(10) Pub. No.: US 2009/0160001 A1
(43) Pub. Date: Jun. 25, 2009

(54) IMAGE SENSOR AND METHOD FOR MANUFACTURING THE SENSOR

(76) Inventor: Dae-Young Kim, Suwon-si (KR)

Correspondence Address: SHERR & VAUGHN, PLLC, 620 HERNDON PARKWAY, SUITE 200, HERNDON, VA, 20170, US

(21) Appl. No.: 12/199,554

(22) Filed: Aug. 27, 2008

(30) Foreign Application Priority Data
Dec. 24, 2007 (KR) 1020070136249

(51) Int. Cl. H01L 31/0232

(52) U.S. Cl. 257/432; 438/70; 257/E31.127

(57) ABSTRACT

An image sensor and a method for manufacturing the same are disclosed. The image sensor manufacturing method may include forming a hard mask pattern over a semiconductor substrate to cover a photodiode region; forming convex photodiodes by wet-etching the photodiode region in the semiconductor substrate using the hard mask pattern; removing the hard mask pattern; forming an interlayer insulating film over the photodiode; forming color filter layers aligned with the photodiodes over the interlayer insulating film; and forming microlenses over the color filter layers. The resulting image sensor can transduce a greater quantity of light as compared to the related art, owing to an increased unit surface area, resulting in enhanced optical efficiency characteristics.

The present application claims priority under 35 U.S.C. 119 to Korean Patent Application No. 10-2007-0136249 (filed on Dec. 24, 2007), which is hereby incorporated by reference in its entirety.

### BACKGROUND

Generally, an image sensor is a semiconductor device used to convert an optical image into an electrical signal. Image sensors may be broadly classified into Charge Coupled Device (CCD) and Complementary Metal Oxide Silicon (CMOS) image sensors.

In a CCD, a plurality of photodiodes (PDs) are arranged in a matrix to convert an optical signal into an electrical signal. A plurality of Vertical Charge Coupled Devices (VCCDs) are formed between vertical photodiodes arranged in a matrix and vertically transmit charges produced from the respective photodiodes. A plurality of Horizontal Charge Coupled Devices (HCCDs) horizontally transmit the charges transmitted by the respective VCCDs. A sense amplifier senses the horizontally transmitted charges to output an electrical signal.

However, a CCD has several disadvantages. It requires a complex drive method, consumes a lot of electricity, and has a complex manufacturing process due to the need for a multi-stage photo-process. In addition, since integrating a control circuit, a signal processing circuit, an analogue/digital converting circuit (A/D converter), etc. onto a CCD chip is difficult, products using a CCD are more difficult to miniaturize.

CMOS image sensors have been viewed as next-generation image sensors capable of overcoming the disadvantages of CCDs. The CMOS image sensor is a device configured such that MOS transistors, corresponding to the number of unit pixels, are formed over a semiconductor substrate using a CMOS technology. A control circuit, a signal processing circuit, etc. may be integrated on the chip and utilized as peripheral circuits, thereby providing a switching means for sequentially detecting outputs of the respective unit pixels via the MOS transistors.

Specifically, in the CMOS image sensor, a photodiode and MOS transistors are formed within a unit pixel. The CMOS image sensor can reproduce an image by sequentially detecting electrical signals of the respective unit pixels in a switched fashion. An image sensor based on CMOS manufacturing technology has the advantages of relatively low electricity consumption, a simple manufacturing process due to a relatively small number of photo-process steps, etc.

In a CMOS image sensor, a control circuit, a signal processing circuit, an analogue/digital converting circuit, etc., can be integrated into a CMOS image sensor chip, and therefore, the size of products can be easily reduced. For this reason, the CMOS image sensor may be used in a variety of applications, such as digital still cameras, digital video cameras, etc.

FIG. 1 is an equivalent circuit diagram of a general 4T-type CMOS image sensor, and FIG. 2 is a layout illustrating a unit pixel of the general 4T-type CMOS image sensor. As shown in FIG. 1, a unit pixel 100 of the CMOS image sensor includes a photodiode 10 as an electrical-to-optical converter, and four transistors. The four transistors include a transfer transistor 20, a reset transistor 30, a drive transistor 40, and a selection transistor 50.

An output end OUT of each unit pixel 100 is electrically connected to a rod transistor 60. Reference letters FD represents a floating diffusion region, Tx represents a gate voltage of the transfer transistor 20, Rx represents a gate voltage of the reset transistor 30, Dx represents a gate voltage of the drive transistor 40, and Sx represents a gate voltage of the selection transistor 50.

The unit pixel of the general 4T-type CMOS image sensor, as shown in FIG. 2, has an active region. A device isolation film is formed throughout the region excluding the active region. A single photodiode PD is formed in a widest portion of the active region, and gate electrodes 23, 33, 43 and 53 of the four transistors are formed over the remaining portion to overlap the active region.

Specifically, the transfer transistor 20 is formed by the gate electrode 23, the reset transistor 30 is formed by the gate electrode 33, the drive transistor 40 is formed by the gate electrode 43, and the selection transistor 50 is formed by the gate electrode 53. Dopant ions are implanted into the active regions of the transistors except for the lower side of the gate electrodes 22, 33, 43 and 53, to form source/drain regions S/D of the transistors.

An image sensor, which consists of a plurality of pixels densely aligned in rows and columns, includes a photodiode PD to sense light from the outside so as to produce photo-electrons. A floating diffusion region FD transmits charges produced from the photodiode. A transfer transistor Tx transmits the charges produced from the photodiode PD into the floating diffusion region FD between the photodiode PD and the floating diffusion region FD, etc.

The operation sequence of the CMOS image sensor having the configuration described above will be described in brief. When the reset transistor Rx is turned on, an output floating diffusion node potential assumes a value VDD. A reference value is detected. Next, when light is irradiated from the outside of the image sensor into the photodiode PD, electron-hole pairs (EHP) are produced in proportion to the quantity of incident light. As the photodiode PD produces signal charges, a source node potential of the transfer transistor Tx varies in proportion to the quantity of the produced signal charges. Subsequently, when the transfer transistor Tx is turned on, the accumulated signal charges are transmitted into the floating diffusion region FD. Thereby, in proportion to the quantity of the transmitted signal charges, the output floating diffusion node potential varies, and simultaneously, a gate bias of the drive transistor Dx varies. This results in variation in a source potential of the drive transistor Dx. At this time, if the selection transistor Sx enters an On-state, data is read out along a column. Thereafter, as the reset transistor Rx is turned on, the output floating diffusion node potential assumes a value V_{DD}. This operation may then be repeated. Hereinafter, a related CMOS image sensor will be described with reference to the accompanying drawings.

FIG. 3 is a sectional view illustrating a related CMOS image sensor. As shown in FIG. 3, the related CMOS image sensor includes a semiconductor substrate 101, which has a device isolation region and an active region. A device isolation film 102 is formed in the device isolation region. Photodiode regions 103 are formed in the active region of the semiconductor substrate 101. An interlayer insulating film 104 is formed throughout the semiconductor substrate 101 including the photodiode regions 103. A planarized layer 105 may be formed over the interlayer insulating film 104. Red, Green and Blue color filter layers 106 may be formed over the planarized layer 105 to correspond to the respective photodiode regions 103. A planarized layer 107 may be formed throughout the semiconductor substrate 101 including the respective color filter layers 106. Microlenses 108 may be formed over the planarized layer 107 to correspond to the respective color filter layers 106. A variety of transistors and metal wirings may be formed in the active region of the semiconductor substrate 101.

In the related CMOS image sensor having the configuration described above, the color filter layers 106 for different colors are formed above the photodiode regions 103 to receive red R, green G and blue B signals. The microlenses 108 are formed at the uppermost end of a light receiving part, to receive a greater quantity of light. The signals are transmitted to an image processing circuit provided outside the light receiving part through a plurality of metal wirings, to be recombined into a single image via a signal processing operation.

The CMOS image sensor described above has excellent photosensitivity, proportional to the quantity of received light. However, even if the photodiode areas are widely spaced apart in a plane to increase the quantity of incident light as much as possible and to enhance the photosensitivity, the related image sensor is limited to a predetermined area in which the photodiode region may widen.

### SUMMARY

Embodiments relate to an image sensor, and more particularly, to an image sensor having an improved optical efficiency and a method for manufacturing the sensor. Embodiments relate to an image sensor which has a spherical convex or concave photodiode, and a method for manufacturing the image sensor.

Embodiments relate to a method for manufacturing an image sensor which may include: forming a hard mask pattern over a semiconductor substrate to cover a photodiode region; forming convex photodiodes by wet-etching the photodiode region in the semiconductor substrate using the hard mask pattern; removing the hard mask pattern; forming an interlayer insulating film over the photodiode; forming color filter layers aligned with the photodiodes over the interlayer insulating film; and forming microlenses over the color filter layers.

Embodiments relate to a method for manufacturing an image sensor which may include: forming a hard mask pattern over a semiconductor substrate to expose a photodiode region; forming concave photodiodes by wet-etching the photodiode region in the semiconductor substrate by use of the hard mask pattern; removing the hard mask pattern; forming an interlayer insulating film over the photodiode; forming color filter layers aligned with the photodiodes over the interlayer insulating film; and forming microlenses over the color filter layers.

Embodiments relate to an image sensor which may include a plurality of convex photodiodes formed over a semiconductor substrate. An interlayer insulating film may be formed over the plurality of photodiodes. Color filter layers may be formed over the interlayer insulating film and aligned with the plurality of photodiodes. Microlenses may be formed over the color filter layers.

Embodiments relate to an image sensor which may include a plurality of concave photodiodes formed over a semiconductor substrate. An interlayer insulating film may be formed over the plurality of photodiodes. Color filter layers may be formed over the interlayer insulating film and aligned with the plurality of photodiodes. Microlenses may be formed over the color filter layers.

### DRAWINGS

FIG. 1 is an equivalent circuit diagram of a 4T-type CMOS image sensor.

FIG. 2 is a layout illustrating a unit pixel of the 4T-type CMOS image sensor.

FIG. 3 is a sectional view illustrating a related CMOS image sensor;

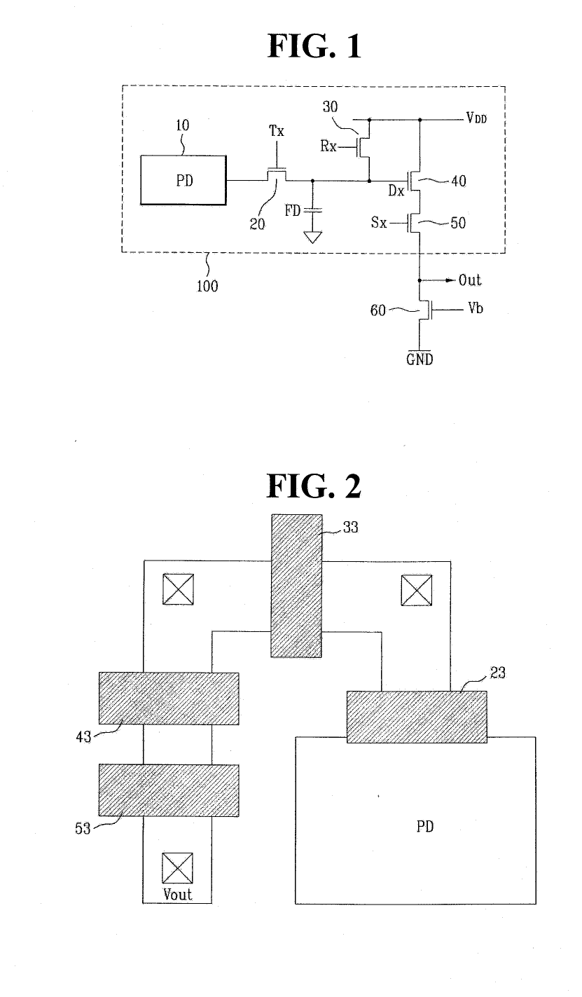

Example FIG. 4 is a sectional view illustrating an image sensor according to embodiments.

Example FIGS. 5A to 5D are process sectional views illustrating a method for manufacturing an image sensor according to embodiments.

Example FIG. 6 is a sectional view illustrating an image sensor according to embodiments.

Example FIGS. 7A to 7D are process sectional views illustrating a method for manufacturing an image sensor according to embodiments.

Example FIG. 8 is a detailed view illustrating a concave photodiode shown in example FIG. 6 or example FIG. 7D.

Example FIGS. 9 and 10 are sectional views of image sensors according to embodiments.

### DESCRIPTION

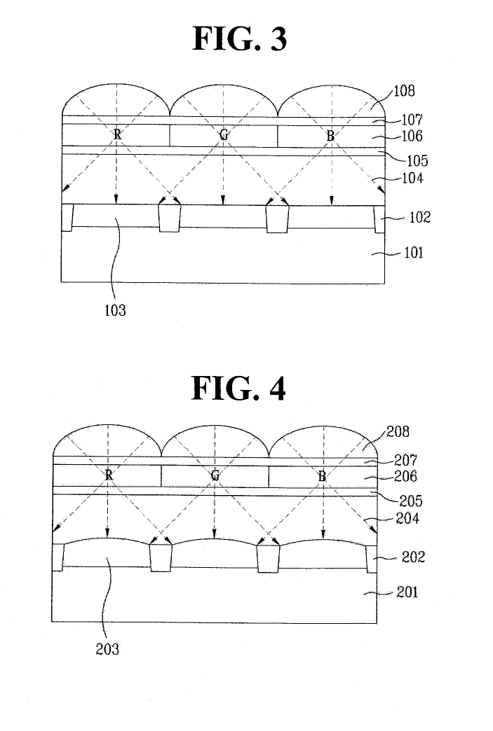

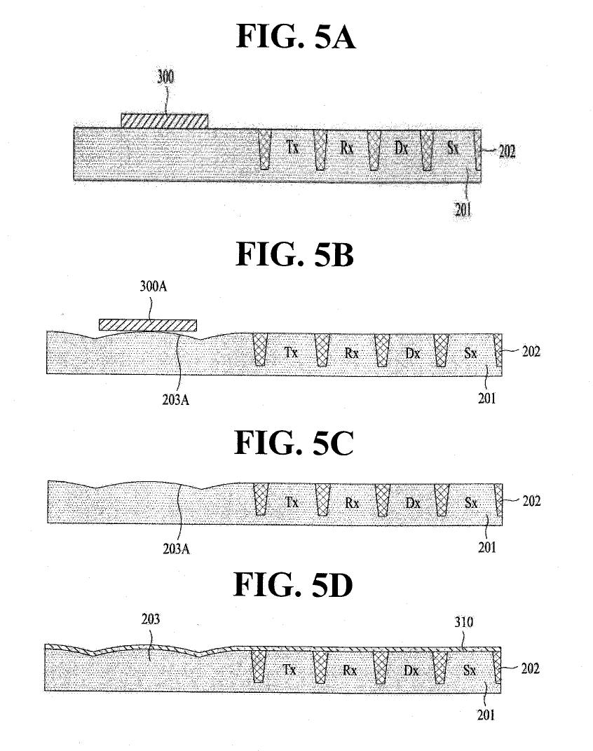

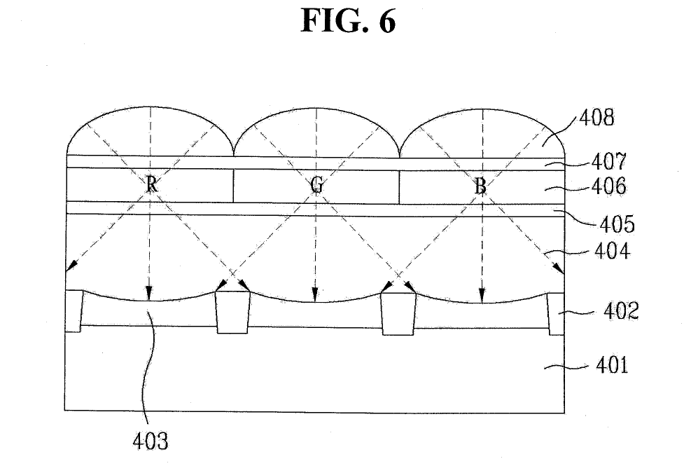

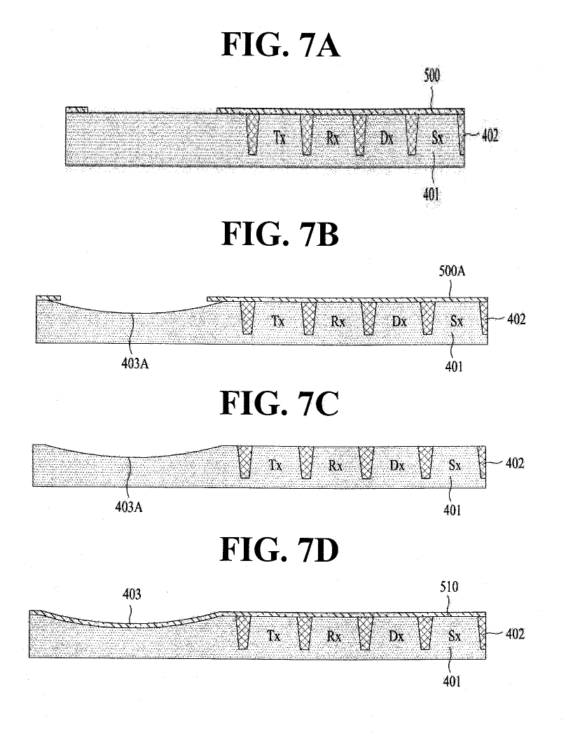

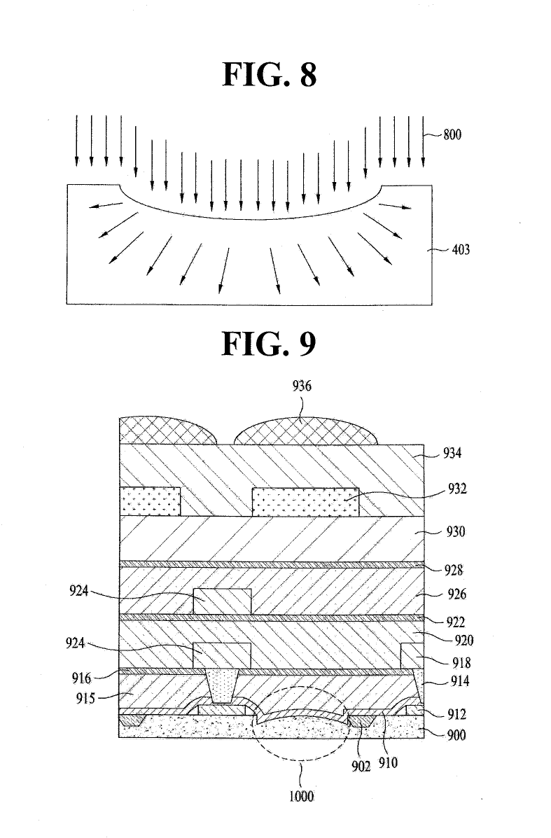

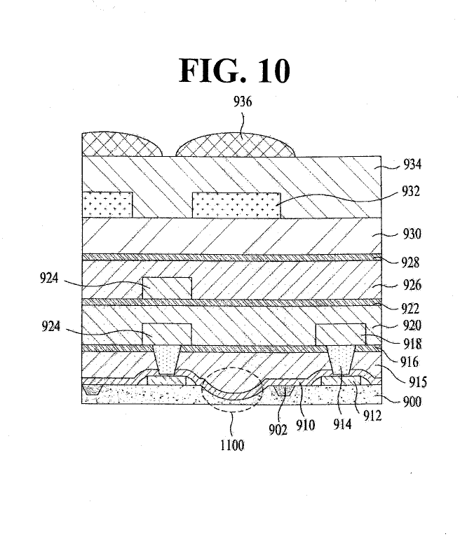

Example FIG. 4 is a sectional view illustrating an image sensor according to embodiments. Referring to example FIG. 4, a plurality of convex photodiodes 203 may be formed over a semiconductor substrate 201. The photodiodes 203 may be separated from one another by a device isolation film 202. In the previously described related image sensor shown in FIG. 3, the photodiodes 103 have a flat shape. However, the image sensor according to embodiments as shown in example FIG. 4 may have convex photodiodes 203, and thus, can receive a considerably increased quantity of light as compared to the related image sensor.

An interlayer insulating film 204 may be formed over the convex photodiodes 203 and the device isolation film 202. Also, a protective layer (or a planarized layer) 205 may be formed over the interlayer insulating film 204, and serves to prevent scratching and protect the device from moisture on the interlayer insulating film 204. Color filter layers 206 may be formed over the protective layer 205 above the photodiodes 203. Color filter layers 206 serve to pass red R, green G and blue B light of specific wavelengths.

Planarized layer 207 may be formed over color filter layers 206. Microlenses 208 may be formed over planarized layer 207 above the photodiodes 203. Microlenses 208 may be shaped into convex lenses having a predetermined curvature, and serve to focus a greater quantity of light to the photodiodes 203 through the color filter layers 206. The curvature and height of microlenses 208 may be determined with consideration of several factors, such as focal point of the focused light, etc.

Hereinafter, a method for manufacturing the image sensor according to embodiments will be described with reference to the accompanying drawings. Example FIGS. 5A to 5D are process sectional views illustrating a method for manufacturing an image sensor according to embodiments. The manufacturing method can be used to manufacture the convex photodiodes 203 as shown in example FIG. 4.

Referring to example FIG. 5D, the semiconductor substrate 201 may be defined as having separate areas including a photodiode region, a device isolation region and an active region. The photodiodes 203 may be formed in the photodiode region, the device isolation film 202 may be formed in the device isolation region, and a variety of transistors Tx, Rx, Dx and Sx may be formed in the active region.

First, referring to example FIG. 5A, device isolation film 202 may be formed in the device isolation region of the semiconductor substrate 201. Next, hard mask pattern 300 may be formed to cover either a part of the photodiode region or the entire photodiode region. For example, the hard mask pattern 300 may be formed to cover only a central region of the photodiode region. According to embodiments, the hard mask pattern 300 may be a TetraEthyl OrthoSilicate (TEOS) film, or may be a thermal oxide film. For example, the hard mask pattern 300 may be formed by depositing a TEOS material layer throughout the semiconductor substrate 201, and patterning the deposited TEOS material layer by photography and etching processes.

As shown in example FIG. 5B, the photodiode region of the semiconductor substrate 201 is subjected to wet-etching using the hard mask pattern 300, to form the convex photodiodes 203. During the wet-etching of the photodiode region, the hard mask pattern 300 may be slightly etched, too. For example, if the hard mask pattern 300 is a TEOS film, a nitric acid (HNO₃) solution can be used as a wet etchant. Alternatively, if the hard mask pattern 300 is a thermal oxide film, a buffered oxide etchant can be used as a wet etchant.

As shown in example FIG. 5C, the hard mask pattern 300 may be removed. Thereafter, as shown in example FIG. 5D, after removing the hard mask pattern 300, an oxide film 310 may be formed over the etched semiconductor substrate 201 via rapid thermal treatment. For example, the oxide film 310 may have a thickness of 10 Å to 20 Å. After forming the convex photodiodes 203, subsequent processes can be carried out using related methods. For example, polysilicon may be deposited to form a gate pattern, and N-type ions may be implanted into the photodiode region.

Subsequently, the interlayer insulating film 204 may be formed over the photodiodes 203. In turn, the protective layer 205 may be formed over the interlayer insulating film 204, and the color filter layers 206 may be formed over the protective layer 205. Specifically, the R, G and B color filter layers 206 can be formed to filter light of different wavelengths as a burnable resist is applied to the protective layer 205 and is patterned. Thereafter, the planarized layer 207 may be formed over the color filter layers 206. The planarized layer 207 provides focal distance adjustment characteristics and planarity required to form a lens layer over the color filter layers 206. The microlenses 208 may be formed over the planarized layer 207.

Hereinafter, an image sensor according to embodiments will be described with reference to the accompanying drawings. Example FIG. 6 is a sectional view illustrating an image sensor according to embodiments.

Referring to example FIG. 6, a plurality of concave photodiodes 403 are formed over a semiconductor substrate 401. The respective photodiodes 403 are separated from one another by a device isolation film 402. In the previously described related image sensor shown in FIG. 3, the photodiodes 103 have a flat shape. However, an image sensor according to embodiments shown in example FIG. 6 has concave photodiodes 403, and thus, can receive a considerably increased quantity of light as compared to the related image sensor.

An interlayer insulating film 404 may be formed over the concave photodiodes 403 and the device isolation film 402. Also, a protective layer 405 is formed over the interlayer insulating film 404, and color filter layers 406 are formed over the protective layer 405. The color filter layers 406 serve to pass red R, green G and blue B light of specific wavelengths.

A planarized layer 407 may be formed over the color filter layers 406. The planarized layer 407 provides planarity and focal distance adjustment characteristics required to form a lens layer over the color filter layers 406. Microlenses 408 may be formed over the planarized layer 407 and aligned with photodiodes 403. The microlenses 408 may be convex lenses having a predetermined curvature, and serve to focus a greater quantity of light to the photodiodes 403 through the color filter layers. The curvature and height of microlenses 408 may be determined with consideration towards several factors such as a focal point of the focused light, etc.

Hereinafter, a method for manufacturing the image sensor according to embodiments will be described with reference to the accompanying drawings. Example FIGS. 7A to 7D are process sectional views illustrating a method for manufacturing an image sensor according to embodiments. The manufacturing method can be used to manufacture the concave photodiodes 403 as shown in example FIG. 6.

The semiconductor substrate 401 may be defined with a photodiode region, a device isolation region and an active region. The photodiodes 403 are formed in the photodiode region, the device isolation film 402 is formed in the device isolation region, and a variety of transistors Tx, Rx, Dx and Sx are formed in the active region.

First, referring to example FIG. 7A, the device isolation film 402 may be formed in the device isolation region of the semiconductor substrate 401. Next, a hard mask pattern 500 may be formed to expose a part of the photodiode region or the entire photodiode region. For example, the hard mask pattern 500 may be formed to expose only a central region of the photodiode region. According to embodiments, the hard mask pattern 500 may be a TEOS film, or may be a thermal oxide film. For example, the hard mask pattern 300 may be formed by depositing a TEOS material layer throughout the semiconductor substrate 401, and patterning the deposited TEOS material layer by photography and etching processes.

As shown in example FIG. 7B, the photodiode region of the semiconductor substrate 401 may be subjected to wet-etching using the hard mask pattern 500, to form the concave photodiodes 403. During the wet-etching of the photodiode region, the hard mask pattern 500 may be slightly etched, too. For example, if the hard mask pattern 500 is a TEOS film, a nitric acid solution can be used as a wet etchant. Alternatively, if the hard mask pattern 500 is a thermal oxide film, a buffered oxide etchant can be used as a wet etchant.

As shown in example FIG. 7C, the hard mask pattern 500 may be removed. Thereafter, as shown in example FIG. 7D, after removing the hard mask pattern 500, an oxide film 510 may be formed over the etched semiconductor substrate 401 via rapid thermal treatment. For example, the oxide film 510 may have a thickness of 10 Å to 20 Å.

After forming the concave photodiodes 403, subsequent processes can be carried out according to related methods. For example, polysilicon may be deposited to form a gate pattern, and N-type ions are implanted into the photodiode region. Subsequently, the interlayer insulating film 404 may be formed over the photodiodes 403. In turn, a protective layer 405 may be formed over the interlayer insulating film 404. The protective layer 405 serves to prevent scratching and protect a device from moisture on the interlayer insulating film 404. The color filter layers 406 may be formed over the protective layer 405. Specifically, the R, G and B color filter layers 406 can be formed to filter light of different wavelengths as a burnable resist which may be applied to the protective layer 405 and patterned. Thereafter, the planarized layer 407 may be formed over the color filter layers 406, and the microlenses 408 may be formed over the planarized layer 407.

The microlenses 208 or 408 shown in example FIG. 4 or example FIG. 6 can be formed using various methods. For example, the microlenses 208 or 408 may be formed by depositing a microlens material layer, for example, resist or SiON over the planarized layer 207 or 407. The deposited microlens material layer may be selectively patterned to allow the deposited microlens material layer to reflow so as to align the resulting microlenses with the photodiodes 203 or 403. The microlenses 208 or 408 may be formed into a semispherical shape as shown in example FIG. 4 or example FIG. 6. The microlenses 208 or 408 may be formed to have an optimum size, thickness and curvature radius, which are determined by the size, position and shape of a unit pixel, the thickness of the photosensitive devices 203 or 403, and the height, position and size of a light-shielding layer, etc.

Example FIG. 8 is a detailed view illustrating the concave photodiode 403 shown in example FIG. 6 or example FIG. 7D. As shown in example FIG. 8, when the photodiode 403 has a concave shape, incident light 800 spreads towards an outer periphery, whereby a unit surface area capable of absorbing the light 800 can be increased based on the same quantity of light. Accordingly, an image sensor with the concave photodiode 403 can achieve a greater electron generation efficiency based on light emission, as compared to the related art.

The image sensor described above according to embodiments is not limited to the configuration shown in example FIG. 4 or example FIG. 6 so long as the photodiodes 203 or 403 have a convex or concave light receiving surface. For example, the interlayer insulating layer 204 may be composed of a plurality of insulating films. Although example FIG. 4 or example FIG. 6 illustrates importantly only the photodiodes 203 or 403 included in the image sensor, it will be clearly understood that other image sensors further include a variety of transistors Tx, Rx, Sx and Dx, including contact plugs and metal wirings.

Hereinafter, other configurations of image sensors using the above-described convex or concave photodiodes will be described in brief with reference to the accompanying drawings. Example FIGS. 9 and 10 are sectional views of image sensors according to embodiments. The image sensors shown in example FIGS. 9 and 10 are substantially identical to each other except that photodiode 1000 shown in example FIG. 9 has a convex shape and photodiode 1100 shown in example FIG. 10 has a concave shape. The method of forming the convex photodiode 1000 or the concave photodiode 1100 is identical to the above description with relation to example FIGS. 5A to 5D and example FIGS. 7A to 7D.

Referring to example FIGS. 9 and 10, a semiconductor substrate 900 may be defined by a device isolation layer 902 as having an active region and a device isolation region. Also, the photodiode 1000 or 1100 may be formed in a photodiode region. A gate pattern 912 may be formed over the semiconductor substrate 900. The gate pattern 912 may include a poly-gate, a gate insulating film formed between the poly-gate and the semiconductor substrate 900, and a spacer formed at sidewalls of the poly-gate and the gate insulating film. A silicon nitride (SiN) film 910 may be formed over the semiconductor substrate 900 and the gate pattern 912.

An insulating film 915 such as an Un-doped Silica Glass (USG) insulting film may be formed over the semiconductor substrate 900 including the gate pattern 912 and the photodiode 1000 or 1100. Two layers of interlayer insulating films 920 and 926, as Inter-Metal Dielectrics (IMDs), may be formed over the insulating film 915 with three insulating barrier films 916, 922 and 928 arranged above, below, and therebetween. Contact plugs 914 may be formed in the insulating film 915, and metal wirings 918 and 924 may be electrically connected to the contact plugs 914. The metal wirings 918 and 924 may be formed in the interlayer insulting films 920 and 926. Capping layers 930 and 934 may be sequentially formed over the uppermost insulating barrier film 928. Color filter layers 932, which may be identical to the above-described color filter layers 206 or 406, may be formed in the capping layer 934. Microlenses 936, which correspond to the microlenses 208 or 408 shown in example FIG. 4 or example FIG. 6, may be formed over the capping layer 934. Here, the capping layer 934 may be made of an oxide film.

In the image sensor and the method for manufacturing the image sensor according to embodiments, the convexity or concavity of photodiodes can be changed according to the height and other critical dimensions of a hard mask pattern and wet-etching process conditions and therefore, the convex or concave photodiodes can be easily changed in configuration to optimize light focusing.

As apparent from the above description, as distinguished from related image sensors having planar two-dimensional photodiodes, the image sensor according to embodiments adopts spherical three-dimensional convex or concave photodiodes similar to microlenses formed thereabove, thereby being capable of transducing a greater quantity of light as compared to the related art, owing to an increased unit surface area.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a hard mask pattern over a semiconductor substrate to cover a photodiode region;
forming convex photodiodes by wet-etching the photodiode region in the semiconductor substrate using the hard mask pattern;
removing the hard mask pattern;
forming an interlayer insulating film over the photodiode;
forming color filter layers aligned with the photodiodes over the interlayer insulating film; and
forming microlenses over the color filter layers.

2. The method of claim 1, wherein said forming the hard mask pattern comprises:
depositing a tetraethyl orthosilicate material layer over the semiconductor substrate; and
patterning the tetraethyl orthosilicate material layer using photolithography processes to form a hard mask pattern covering only a central portion of the photodiode region.

3. The method of claim 2, wherein said forming the convex photodiodes comprises subjecting the photodiode region to wet-etching using a nitric acid solution as a wet etchant.

4. The method of claim 1, wherein said forming the hard mask pattern comprises:
forming a thermal oxide film over the semiconductor substrate; and
patterning the thermal oxide film by photolithography processes to form a hard mask pattern covering only a central portion of the photodiode region.

5. The method of claim 4, wherein said forming the convex photodiodes comprises wet etching the photodiode region using a buffered oxide etchant.

6. The method of claim 1, comprising forming an oxide film over the wet-etched semiconductor substrate including the photodiodes via rapid thermal treatment after said removing the hard mask pattern.

7. The method of claim 6, wherein the oxide film has a thickness of about 10 Å to 20 Å.

8. A method comprising:
forming a hard mask pattern over a semiconductor substrate to expose a photodiode region;
forming concave photodiodes by wet-etching the photodiode region in the semiconductor substrate by use of the hard mask pattern;
removing the hard mask pattern;
forming an interlayer insulating film over the photodiode;
forming color filter layers aligned with the photodiodes over the interlayer insulating film; and
forming microlenses over the color filter layers.

9. The method of claim 8, wherein said forming the hard mask pattern comprises:
depositing a tetraethyl orthosilicate material layer over the semiconductor substrate; and
patterning the tetraethyl orthosilicate material layer by photolithography processes to form a hard mask pattern covering only a central portion of the photodiode region.

10. The method of claim 9, wherein said forming the concave photodiodes comprises subjecting the photodiode region to wet-etching using a nitric acid solution as a wet etchant.

11. The method of claim 8, wherein said forming the hard mask pattern comprises:
forming a thermal oxide film over the semiconductor substrate; and
patterning the thermal oxide film by photolithography processes to form the hard mask pattern covering only a central portion of the photodiode region.

12. The method of claim 11, wherein said forming the concave photodiodes comprises wet etching the photodiode region using a buffered oxide etchant.

13. The method of claim 8, comprising forming an oxide film over the wet-etched semiconductor substrate including the photodiodes via rapid thermal treatment after said removing the hard mask pattern.

14. The method of claim 13, wherein the oxide film has a thickness of about 10 Å to 20 Å.

15. An apparatus comprising:
a plurality of convex photodiodes formed over a semiconductor substrate;
an interlayer insulating film formed over the plurality of photodiodes;
color filter layers over the interlayer insulating film and aligned with the plurality of photodiodes; and
microlenses formed over the color filter layers.

16. The apparatus of claim 15, comprising a device isolation film to separate the plurality of photodiodes from one another.

17. The apparatus of claim 16, further comprising an oxide film formed between the plurality of photodiodes and the interlayer insulating film.

18. An apparatus comprising:
a plurality of concave photodiodes formed over a semiconductor substrate;
an interlayer insulating film formed over the plurality of photodiodes;
color filter layers over the interlayer insulating film and aligned with the plurality of photodiodes; and
microlenses formed over the color filter layers.

19. The apparatus of claim 18, comprising a device isolation film to separate the plurality of photodiodes from one another.

20. The apparatus of claim 19, comprising an oxide film formed between the plurality of photodiodes and the interlayer insulating film.
